(19) United States
(12) Patent Application Publication
(10) Pub. No.: US 2023/0066074 A1
(43) Pub. Date: Mar. 2, 2023

(54) DISPLAY PANEL

(71) Applicant: HannStar Display Corporation, Taipei City (TW)

(72) Inventors: Chung Lin Chang, Kaohsiung City (TW); Hsuan-Chen Liu, Kaohsiung City (TW); Cheng-Yen Yeh, Taichung City (TW); Yu-Cheng Lin, Pingtung County (TW); Chen-Hao Su, Taichung City (TW)

(73) Assignee: HannStar Display Corporation, Taipei City (TW)

(21) Appl. No.: 17/885,571

(22) Filed: Aug. 11, 2022

(30) Foreign Application Priority Data
Aug. 31, 2021 (CN) 202111015248.1

(51) Int. Cl. G02F 1/1362; H01L 27/12; G02F 1/1368; G02F 1/1343; G09G 3/36

(52) U.S. Cl. CPC G02F 1/136263; H01L 27/124; G02F 1/136286; G02F 1/1368; G02F 1/136213; G02F 1/134309; G09G 3/36; H01L 27/1255; G02F 1/133757

(57) ABSTRACT

The disclosure provides a display panel including a first substrate, multiple scan lines, multiple data lines, and multiple pixel structures. The scan lines and the data lines are disposed on the first substrate and intersect each other. One of the pixel structures includes an active element, a pixel electrode, a capacitor electrode, a common electrode, and a repair pattern. The active element includes a source, a drain, and a gate. The gate is electrically connected to one of the scan lines. The source is electrically connected to one of the data lines. The pixel electrode is electrically connected to the drain of the active element. The capacitor electrode is electrically connected to the pixel electrode and extends from the drain. The common electrode overlaps the pixel electrode and the capacitor electrode. The repair pattern overlaps one of the scan lines as well as the common electrode, and the pixel electrode.

### CROSS-REFERENCE TO RELATED APPLICATION

This application claims the priority benefit of China application serial no. 202111015248.1, filed on Aug. 31, 2021. The entirety of the above-mentioned patent application is hereby incorporated by reference herein and made a part of this specification.

### BACKGROUND

### 1. Technical Field

The disclosure relates to a display panel, in particular to a display panel having repair structures.

### 2. Description of Related Art

With the development of liquid crystal display technology, liquid crystal display panels have been widely used in different fields. In the actual production process, the liquid crystal display panels often face the problem of abnormally bright and dark dots due to the manufacturing process or other factors. To reduce the impact of the bright and dark dots on the display quality, multiple repair structures are usually disposed on the pixel array substrate. The repair structures can improve the yield of liquid crystal display panels and reduce production costs. However, the capacitive coupling effect between the repair structures and the signal lines tends to affect the operating electrical properties of the pixel structures, resulting in uneven brightness of the display screen.

### SUMMARY

The disclosure is directed to a display panel in which the repair structures have a less pronounced effect on the operating electrical properties of display pixels and the repair process is simplified.

The display panel according to an embodiment of the disclosure includes a first substrate, multiple scan lines, multiple data lines, and multiple pixel structures. The scan lines and the data lines are disposed on the first substrate and intersect each other. The pixel structures are respectively disposed between the data lines and the scan lines. At least one of the pixel structures includes an active element, a pixel electrode, a capacitor electrode, a common electrode, and a repair pattern. The active element includes a source, a drain, and a gate. The gate is electrically connected to one of the scan lines. The source is electrically connected to one of the data lines. The pixel electrode is electrically connected to the drain of the active element. The capacitor electrode is electrically connected to the pixel electrode and extends from the drain. The common electrode overlaps the pixel electrode and the capacitor electrode. The repair pattern overlaps one of the scan lines as well as the common electrode, and the pixel electrode.

In the display panel according to an embodiment of the disclosure, the at least one of the multiple pixel structures includes a first pixel structure. The multiple scan lines includes a first scan line, and the repair pattern of the first pixel structure and a part of the drain overlap the first scan line.

In the display panel according to the embodiment of the disclosure, the repair pattern, the capacitor electrode, and the drain of the active element are integral.

In the display panel according to the embodiment of the disclosure, the repair pattern of the first pixel structure and the gate of the active element are electrically connected to the first scan line.

In the display panel according to the embodiment of the disclosure, the common electrode includes a first extension portion, a second extension portion, and a connecting portion. The first extension portion and the second extension portion are disposed on opposite sides of the pixel electrode along a first direction and extend in a second direction. The connecting portion extends in the first direction. The connecting portion connects the first extension portion and the second extension portion. The first direction intersects the second direction. The capacitor electrode overlaps the connecting portion of the common electrode.

In the display panel according to the embodiment of the disclosure, the capacitor electrode further overlaps one of the first extension portion and the second extension portion of the common electrode.

In the display panel according to the embodiment of the disclosure, the multiple data lines, multiple first extension portions, and multiple second extension portions are alternately arranged along the first direction.

In the display panel according to an embodiment of the disclosure, the at least one of the multiple pixel structures further includes a second pixel structure. The first pixel structure and the second pixel structure are arranged along a first direction and are electrically connected to a first data line of the multiple data lines. The multiple scan lines further includes a second scan line. The first scan line and the second scan line are located on opposite sides of the first pixel structure and the second pixel structure along a second direction. The first direction intersects the second direction. The first pixel structure is electrically connected to the first scan line, and the second pixel structure is electrically connected to the second scan line.

In the display panel according to the embodiment of the disclosure, the common electrode includes a connecting portion, a first extension portion, and a second extension portion.

The first extension portion and the second extension portion are disposed on opposite sides of the connecting portion along the first direction and are connected to the connecting portion. The capacitor electrode overlaps the connecting portion of the common electrode.

In the display panel according to the embodiment of the disclosure, the first extension portion of the common electrode of the first pixel structure is connected to the first extension portion of the common electrode of the second pixel structure and defines an opening, and the opening overlaps the first data line.

In the display panel according to the embodiment of the disclosure, the capacitor electrode further overlaps the second extension portion of the common electrode.

In the display panel according to an embodiment of the disclosure, the at least one of the multiple pixel structures includes a first pixel structure. The repair pattern of the first pixel structure and the drain of the active element respectively overlap two of the multiple scan lines.

In the display panel according to an embodiment of the disclosure, the at least one of the multiple pixel structures further includes a second pixel structure. The first pixel structure and the second pixel structure are arranged along a first direction and are electrically connected to one of the multiple data lines. The multiple scan lines includes a first scan line and a second scan line. The first scan line and the second scan line are located on opposite sides of the first pixel structure and the second pixel structure along the second direction. The first direction intersects the second direction. The first pixel structure is electrically connected to the first scan line, and the second pixel structure is electrically connected to the second scan line.

In the display panel according to the embodiment of the disclosure, the common electrode includes a connecting portion, a first extension portion, and a second extension portion. The first extension portion and the second extension portion are disposed on opposite sides of the connecting portion along the first direction and are connected to the connecting portion. The repair pattern overlaps the second extension portion of the common electrode.

In the display panel according to the embodiment of the disclosure, the first extension portion of the common electrode of the first pixel structure is connected to the first extension portion of the common electrode of the second pixel structure and defines an opening, and the opening overlaps one of the multiple data lines.

In the display panel according to the embodiment of the disclosure, the capacitor electrode overlaps the connecting portion of the common electrode.

In the display panel according to the embodiment of the disclosure, the repair pattern includes a first end portion, a second end portion, and a third end portion. The first end portion overlaps one of the multiple scan lines. The second end portion overlaps the pixel electrode. The third end portion overlaps the second extension portion of the common electrode. The second end portion is located between the first end portion and the third end portion in the second direction.

In the display panel according to the embodiment of the disclosure, the gate of the active element and the repair pattern of the first pixel structure are respectively electrically connected to the first scan line and the second scan line.

In an embodiment according to the disclosure, the display panel further includes a second substrate, a first alignment layer, a second alignment layer, a liquid crystal layer, a first polarizer, and a second polarizer. The second substrate is disposed opposite to the first substrate. The first alignment layer is disposed on the first substrate and has a first alignment direction. The second alignment layer is disposed on the second substrate and has a second alignment direction.

The first alignment direction is perpendicular to the second alignment direction. The liquid crystal layer is disposed between the first alignment layer and the second alignment layer and includes multiple liquid crystal molecules. Multiple pixel electrodes of the multiple pixel structures are configured to drive the liquid crystal molecules to rotate. The first polarizer and the second polarizer are disposed on opposite sides of the liquid crystal layer and respectively including a first transmission axis and a second transmission axis. An axial direction of the first transmission axis is perpendicular to an axial direction of the second transmission axis.

In the display panel according to an embodiment of the disclosure, the at least one of the multiple pixel structures includes a first pixel structure. The pixel electrode of the first pixel structure is electrically connected to one of the scan lines through the repair pattern.

In summary, in the display panel of an embodiment of the disclosure, the pixel structure includes a repair pattern overlapping the scan line, the common electrode, and the pixel electrode, and includes a capacitor electrode extending from the drain of the active element. Through the overlap of the capacitor electrode and the common electrode, the voltage offset of the pixel electrode due to the capacitive coupling effect between the repair pattern, the scan line, and the pixel electrode can be effectively suppressed, thereby improving the brightness uniformity of the multiple pixel structures of the display panel at the same display grayscale.

### BRIEF DESCRIPTION OF THE DRAWINGS

The accompanying drawings are included to provide a further understanding of the disclosure, and are incorporated in and constitute a part of the disclosure. The drawings illustrate embodiments of the disclosure and, together with the description, serve to explain the principles of the disclosure.

FIG. 1 is a schematic cross-sectional view of a display panel according to a first embodiment of the disclosure.

FIG. 2 is a schematic top view of the display panel of FIG. 1.

FIG. 3 is a schematic top view of the common electrodes and scan lines of FIG. 2.

FIG. 4 is a schematic top view of a display panel according to a second embodiment of the disclosure.

FIG. 5 is a schematic top view of a display panel according to a third embodiment of the disclosure.

FIG. 6 is a schematic top view of the common electrodes and scan lines of FIG. 5.

FIG. 7 is a schematic top view of a display panel according to a fourth embodiment of the disclosure.

FIG. 8 is a schematic top view of a display panel according to a fifth embodiment of the disclosure.

### DESCRIPTION OF THE EMBODIMENTS

Reference will now be made in detail to the exemplary embodiments of the disclosure, and examples of which are illustrated in the accompanying drawings. Whenever possible, the same reference numbers are used in the drawings and the description to refer to the same or like parts. Note that the “overlap” mentioned in the following exemplary embodiments refers to the projection overlap of two objects in one direction. Unless otherwise specified, the direction may be the direction Z in the drawings.

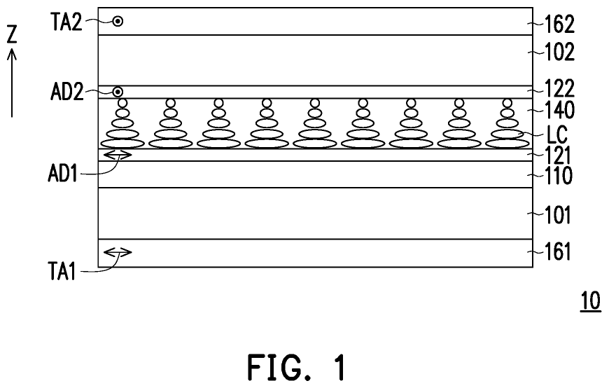

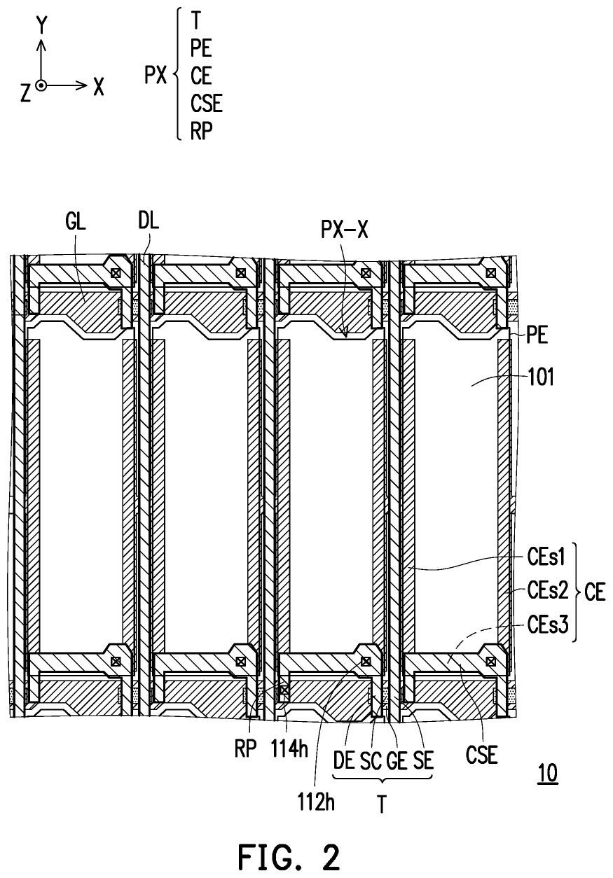

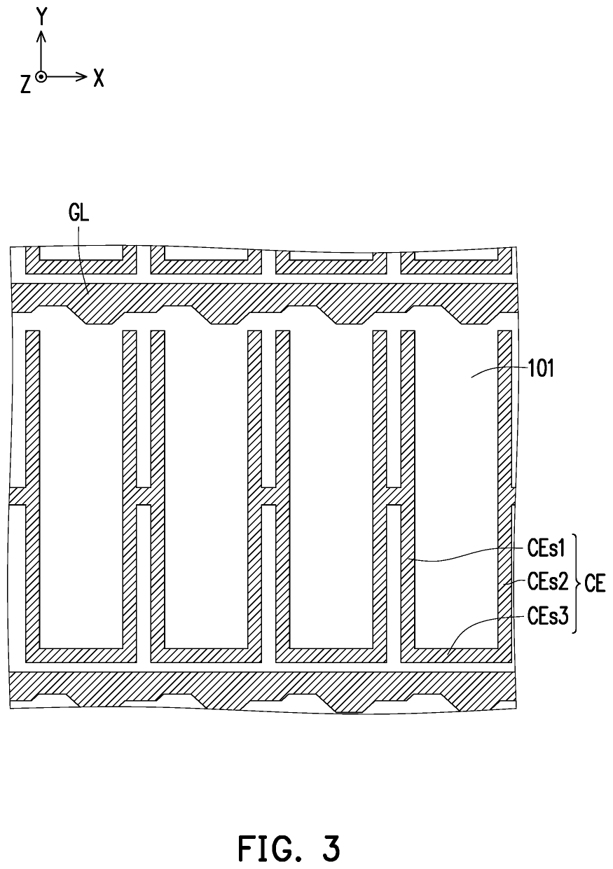

FIG. 1 is a schematic cross-sectional view of a display panel according to a first embodiment of the disclosure. FIG. 2 is a schematic top view of the display panel of FIG. 1. FIG. 3 is a schematic top view of the common electrodes and scan lines of FIG. 2. For the sake of clear presentation, FIG. 2 shows only a first substrate 101 and a pixel driving layer 110 of FIG. 1.

Referring to FIGS. 1 and 2, a display panel 10 includes a first substrate 101, a second substrate 102, the pixel driving layer 110, a first alignment layer 121, a second alignment layer 122, and a liquid crystal layer 140. The first substrate 101 and the second substrate 102 are disposed opposite to each other. The pixel driving layer 110 is disposed on the first substrate 101. The first alignment layer 121 and the second alignment layer 122 are respectively disposed on the first substrate 101 and the second substrate 102. The liquid crystal layer 140 is disposed between the first alignment layer 121 and the second alignment layer 122, and includes multiple liquid crystal molecules LC. The material of the first substrate 101 and the second substrate 102 may be, for example, glass, quartz, high molecular polymer, or other suitable transparent plates.

In this embodiment, the first alignment layer 121 has a first alignment direction AD1. The second alignment layer 122 has a second alignment direction AD2, and the first alignment direction AD1 may be perpendicular to the second alignment direction AD2. More specifically, the liquid crystal molecules LC of the liquid crystal layer 140 are driven in a manner of twisted nematic (TN) arrangement. On the other hand, a first polarizer 161 and a second polarizer 162 are further provided on opposite sides of the liquid crystal layer 140, and a first transmission axis TA1 of the first polarizer 161 is perpendicular to a second transmission axis TA2 of the second polarizer 162. The display panel 10 is operated in a normally white mode, for example. For example, when the liquid crystal layer 140 is not driven by an electric field, the light from the backlight module may directly pass through the display panel 10 to achieve a bright display effect. Conversely, when the liquid crystal layer 140 is driven by an electric field, the light from the backlight module cannot pass through the display panel 10 to achieve a dark display effect. It should be understood that the light here may also be ambient light from the display side. In other words, the display panel may also be a reflective display panel or a transflective display panel, and the multiple liquid crystal molecules LC of the liquid crystal layer 140 may also be driven in a manner of anti-parallel alignment or a vertical alignment (VA) arrangement.

The pixel driving layer 110 includes multiple scan lines GL, multiple data lines DL, and multiple pixel structures PX. The scan lines GL intersect with the data lines DL, and define multiple pixel regions. The pixel structures PX are respectively disposed in the pixel regions between the data lines DL and the scan lines GL. For example, in this embodiment, the scan lines GL are arranged on the first substrate 101 along a direction Y and extend in a direction X. The data lines DL are arranged on the first substrate 101 along the direction X and extend along the direction Y. The direction X and the direction Y intersect. However, the disclosure is not limited thereto. In other embodiments, the scan lines GL may be arranged on the first substrate 101 along the direction X, and the data lines DL may be arranged on the first substrate 101 along the direction Y. Considering conductivity, the scan line GL and the data line DL are generally made of metal materials (i.e. molybdenum, aluminum, copper, nickel, or a combination of the above), but the disclosure is not limited thereto.

The pixel structure PX includes an active element T and a pixel electrode PE. The active element T includes a gate GE, a source SE, a drain DE, and a semiconductor pattern SC. The gate GE and the source SE are respectively electrically connected to a corresponding scan line GL and a data line DL. The source SE and the drain DE are respectively electrically connected to two different regions (i.e. the source region and the drain region) of the semiconductor pattern SC. The pixel electrode PE is electrically connected to the drain DE of the active element T. In this embodiment, the active element T may be a bottom-gate thin-film-transistor. In other words, the gate GE is optionally disposed on the side of the semiconductor pattern SC away from the source SE and the drain DE, but the disclosure is not limited thereto.

In other embodiments, the gate GE of the active element T may also be disposed above the semiconductor pattern SC (that is, the side of the semiconductor pattern SC where the source SE and the drain DE are provided) to form a top-gate thin film transistor (top-gate thin-film-transistor). In this embodiment, the source SE may be a part of the data line DL, and the gate GE may be a part of the scan line GL. Since the semiconductor pattern SC of the active element T overlaps the scan line GL, a part of the drain DE overlaps the scan line GL.

The active element T may be, for example, a polysilicon thin film transistor, an amorphous silicon (a-Si) thin film transistor, or a metal-oxide semiconductor (MOS) transistor, but the disclosure is not limited thereto. Note that the gate GE, the source SE, the drain DE, the semiconductor pattern SC, and a common electrode CE may be respectively implemented by any gate, any source, any drain, any semiconductor pattern, and any common electrode of the display panel that is well known to those skilled in the art. Moreover, the gate GE, the source SE, the drain DE, the semiconductor pattern SC, and the common electrode CE may be respectively formed by any method known to those skilled in the art, so they will not be described in detail here.

On the other hand, the pixel electrode PE may be, for example, a light-transmitting electrode, and the material of the light-transmitting electrode includes metal oxide (i.e. indium tin oxide, indium zinc oxide, aluminum tin oxide, aluminum zinc oxide, or other suitable oxides, or a stacked layer of at least two of the above), but the disclosure is not limited thereto. In other embodiments, the pixel electrode PE may also include a reflective electrode, and the material of the reflective electrode includes metals, alloys, nitrides of metal materials, oxides of metal materials, oxynitrides of metal materials, or other suitable materials, or stacked layers of metal materials and other conductive materials.

For example, in this embodiment, a common electrode layer (not shown) may be further provided on the second substrate 102. Further, the electric field generated between the pixel electrode PE and the common electrode layer when the pixel electrode PE is enabled may drive the multiple liquid crystal molecules LC of the liquid crystal layer 140 to rotate and form a corresponding optical axis distribution, thereby modulating the polarization state of the incident light. More specifically, the display panel 10 may individually control the voltage levels of the multiple pixel electrodes PE of the multiple pixel structures PX through multiple scan lines GL and multiple data lines DL such that the multiple pixel regions have the same or different brightness so as to achieve the displayed effect.

Referring to FIG. 3 at the same time, in order to form a storage capacitor of the pixel structure PX, the pixel structure PX further includes a common electrode CE, and the common electrode CE overlaps the pixel electrode PE. In this embodiment, the common electrode CE may include a first extension portion CEs1, a second extension portion CEs2, and a connecting portion CEs3. The first extension portion CEs1 and the second extension portion CEs2 are disposed on opposite sides of the pixel electrode PE along the direction X (i.e. first direction) and extend along the direction Y (i.e. second direction). More specifically, the multiple data lines DL as well as multiple first extension portions CEs1 and multiple second extension portions CEs2 of multiple common electrodes CE are alternately arranged along the direction X. The connecting portion CEs3 extends along the direction X and is connected between the first extension portion CEs1 and the second extension portion CEs2. The multiple common electrodes CE of the multiple pixel structures PX arranged along the direction X are connected to each other. In this embodiment, the common electrodes CE and the scan lines GL may optionally be in the same metal conductive layer, but the disclosure is not limited thereto.

In this embodiment, the pixel structure PX further includes a capacitor electrode CSE and a repair pattern RP. Note in particular that the capacitor electrode CSE extends from the drain DE of the active element T, and overlaps the connecting portion CEs3 of the common electrode CE. The repair pattern RP extends from the capacitor electrode CSE, and overlaps one scan line GL and the pixel electrode PE. In other words, the drain DE, the capacitor electrode CSE, and the repair pattern RP in this embodiment may be optionally integral, but the disclosure is not limited thereto. For example, in this embodiment, the drain DE of the active element T is electrically connected to the pixel electrode PE via the capacitor electrode CSE. The pixel electrode PE is electrically connected to the capacitor electrode CSE through a contact hole 112h of the insulating layer (not shown).

In particular, the repair pattern RP is configured to repair the pixel structure PX. For example, when PX-X, one of the pixel structures of the display panel 10, cannot be enabled and is detected as abnormal, a laser welding procedure may be performed to weld the repair pattern RP and the corresponding scan line GL to each other to be electrically connected. Therefore, after the laser welding step is completed, the insulating layer or the flat layer between the repair pattern RP and the scan line GL will form a melt-through hole 114h. The pixel electrode PE of the repaired pixel structure PX-X is electrically connected to the scan line GL via the capacitor electrode CSE and the repair pattern RP. Therefore, regardless of whether the scan line GL electrically connected to the pixel structure PX-X receives a gate driving signal, the pixel electrode PE of the abnormal pixel structure PX-X always has a higher voltage level. In other words, when the display panel 10 is operated in a normally white mode, the pixel region of the display screen corresponding to the abnormal pixel structure PX-X always maintains a dark state, so as to avoid the degradation of display quality.

On the other hand, through the overlap of the capacitor electrode CSE and the common electrode CE, the voltage offset of the pixel electrode PE due to the capacitive coupling effect between the repair pattern RP, the scan line GL, and the pixel electrode PE can be further suppressed, thereby improving the brightness uniformity of the multiple pixel structures PX of the display panel 10 at the same display grayscale. Moreover, in this embodiment, the repair procedure of the abnormal pixel structure PX-X only includes one laser welding step. Therefore, through the configuration of the capacitor electrode CSE and the repair pattern RP, the effect of simplifying the repair process can be further achieved.

Other embodiments will be listed below to describe the disclosure in detail, in which the same components will be indicated with the same symbols, and the description of the same technical content will be omitted. Please refer to the foregoing embodiments for the omitted parts, which will not be repeated hereafter.

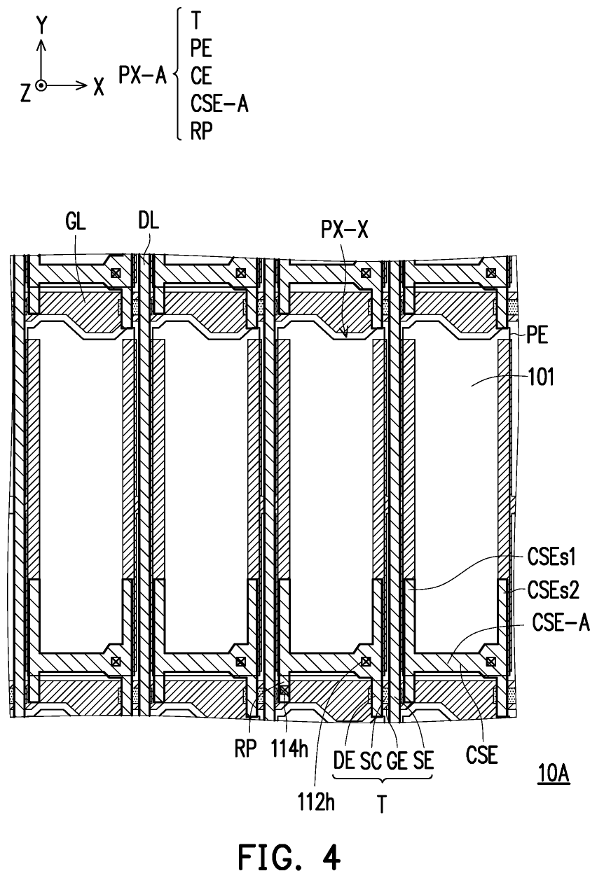

FIG. 4 is a schematic top view of a display panel according to a second embodiment of the disclosure. Referring to FIG. 4, the difference between a display panel 10A of this embodiment and the display panel 10 of FIG. 2 is that the capacitor electrode is configured differently. Specifically, a capacitor electrode CSE-A of a pixel structure PX-A of the display panel 10A also overlaps the first extension portion CEs1 and the second extension portion CEs2 of the common electrode CE. In this embodiment, the capacitor electrode CSE-A includes two extension sections CSEs1 and CSEs2, and the extension section CSEs1 and the extension section CSEs2 respectively overlap the first extension portion CEs1 and the second extension portion CEs2 of the common electrode CE. Accordingly, by increasing the storage capacitance of the pixel structure PX-A so as suppress the voltage offset of the pixel electrode PE due to the capacitive coupling effect between the repair pattern RP, the scanning line GL, and the pixel electrode PE, it helps to improve the brightness uniformity of the multiple pixel structures PX-A of the display panel 10A at the same display grayscale.

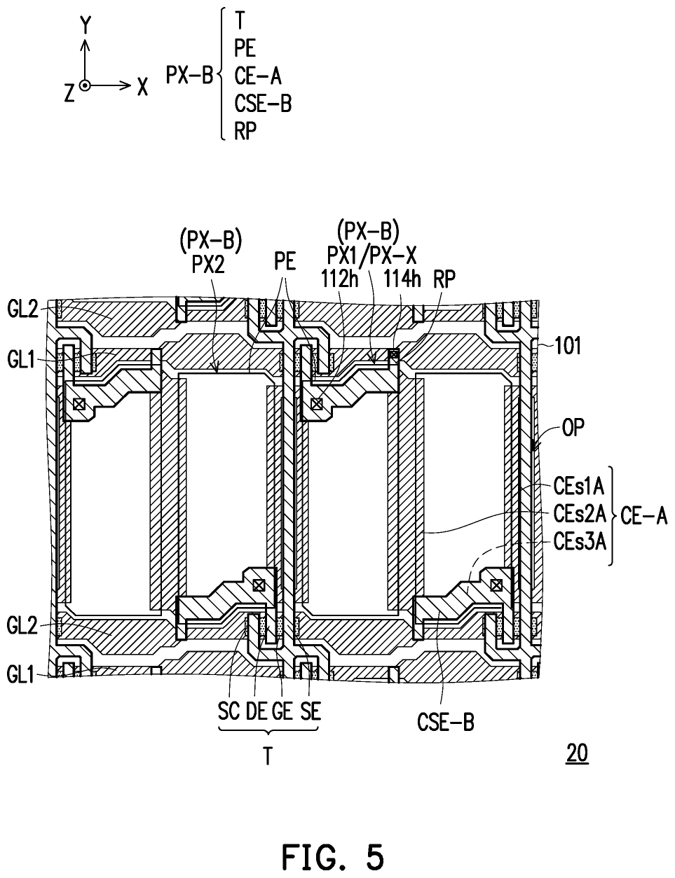

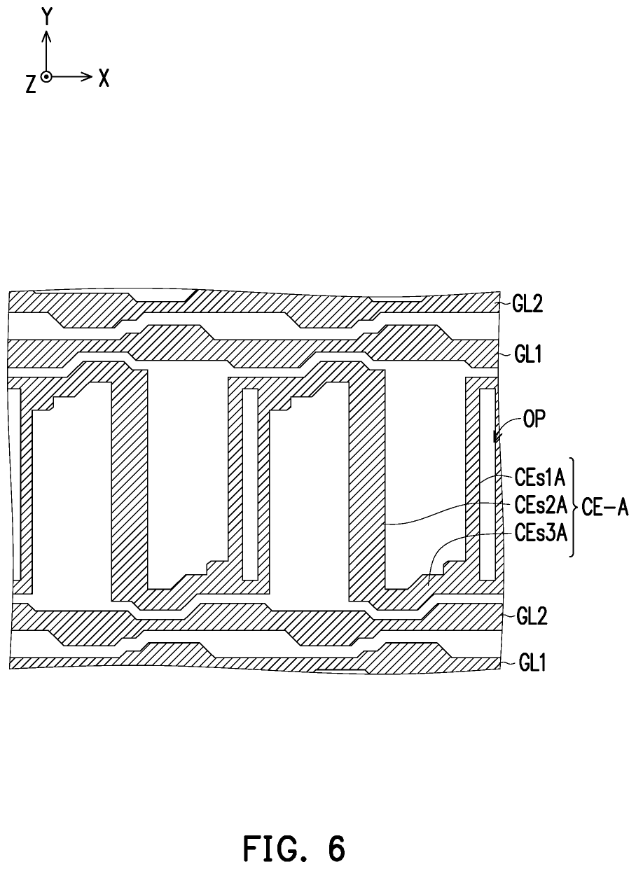

FIG. 5 is a schematic top view of a display panel according to a third embodiment of the disclosure. FIG. 6 is a schematic top view of the common electrodes and scan lines of FIG. 5. Referring to FIGS. 5 and 6, the main difference between a display panel 20 of this embodiment and the display panel 10 of FIG. 2 lies in that the pixel structures, the data lines, and the scan lines are configured differently. In this embodiment, the display panel 20 includes multiple first scan lines GL1 and multiple second scan lines GL2. The first scan lines GL1 and the second scan lines GL2 are alternately arranged on the first substrate 101 along the direction Y. Multiple pixel structures PX-B includes multiple first pixel structures PX1 and multiple second pixel structures PX2. The first pixel structures PX1 and the second pixel structures PX2 are alternately arranged into multiple pixel rows along the direction X, and each pixel row is provided with one first scan line GL1 and one second scan line GL2 on opposite sides in the direction Y.

Two adjacent first pixel structures PX1 and second pixel structures PX2 in each pixel row are electrically connected to the same data line DL, and are respectively electrically connected to the first scan line GL1 and the second scan line GL2.

On the other hand, similar to the common electrode CE of FIG. 3, a common electrode CE-A of this embodiment includes a first extension portion CEs1A, a second extension portion CEs2A, and a connecting portion CEs3A. The first extension portion CEs1A and the second extension portion CEs2A are disposed on opposite sides of the connecting portion CEs3A along the direction X and are connected to the connecting portion CEs3A. Note in particular that the first extension portion CEs1A of the common electrode CE-A of the first pixel structure PX1 in the direction X is connected to the first extension portion CEs1A of the common electrode CE-A of the second pixel structure PX2 adjacent thereof and defines an opening OP. The opening OP overlaps the data line DL. Accordingly, the capacitive coupling effect between the common electrode CE-A and the data line DL can be reduced.

In this embodiment, since the first pixel structure PX1 and the second pixel structure PX2 that are electrically connected to the same data line DL and are adjacent to each other are electrically connected to different scan lines (i.e. the first scan line GL1 and the second scan line GL2), the repair patterns RP of the two pixel structures PX-B also respectively overlap the two scan lines. More specifically, the repair pattern RP of the first pixel structure PX1 extends from a capacitor electrode CSE-B of the first pixel structure PX1, and overlaps the first scan line GL1. The repair pattern RP of the second pixel structure PX2 extends from the capacitor electrode CSE-B of the second pixel structure PX2, and overlaps the second scan line GL2.

When one of the pixel structures PX-B of the display panel 20, such as the first pixel structure PX1, cannot be enabled and is detected as an abnormal pixel structure PX-X, a laser welding procedure may be performed to weld the repair pattern RP and the corresponding first scan line GL1 to each other to be electrically connected. Therefore, when the display panel 20 is operated in a normally white mode, the pixel region of the display screen corresponding to the abnormal pixel structure PX-X always maintains a dark state, so as to avoid the degradation of display quality.

It is worth mentioning that through the overlap of the capacitor electrode CSE-B and the common electrode CE-A, the voltage offset of the pixel electrode PE due to the capacitive coupling effect between the repair pattern RP, the first scan line GL1 (or the second scan line GL2), and the pixel electrode PE, can be suppressed thereby improving the brightness uniformity of the multiple pixel structures PX-B of the display panel 20 at same display grayscale. Moreover, in this embodiment, the repair pattern RP of the pixel structure PX-B extends from the capacitor electrode CSE-B and overlaps the first scan line GL1 or the second scan line GL2, and the repair procedure of the abnormal pixel structure PX-X only includes one laser welding step, thereby achieving the effect of simplifying the repair process.

The overlap of the capacitor electrode CSE-B and the common electrode CE-A in this embodiment is similar to the overlap of the capacitor electrode CSE and the common electrode CE in FIG. 2. Please refer to the relevant paragraphs of the foregoing embodiment for the detailed description, which will not be repeated here.

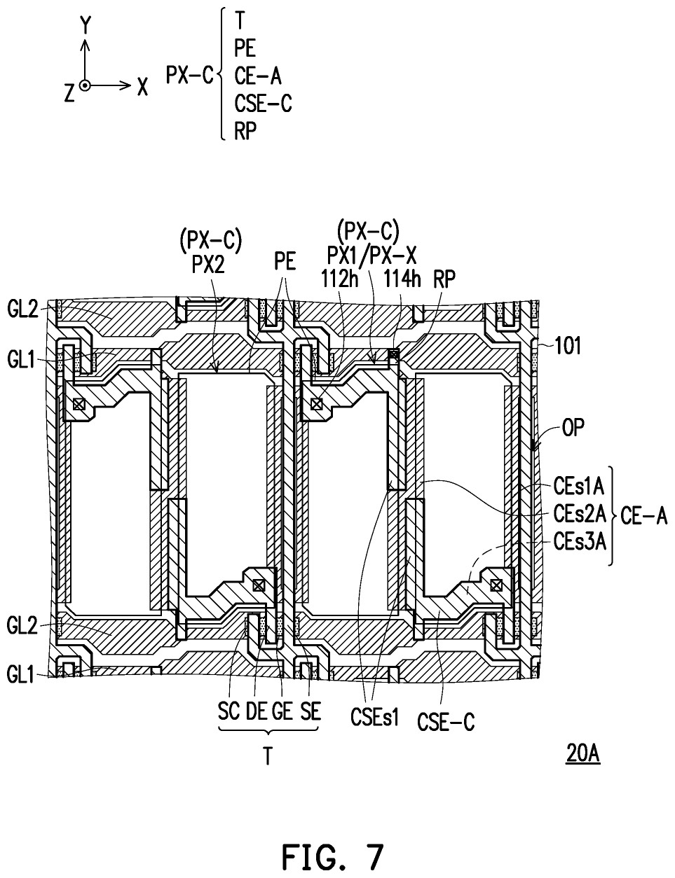

FIG. 7 is a schematic top view of a display panel according to a fourth embodiment of the disclosure. Referring to FIG. 7, the difference between the display panel 20A of this embodiment and the display panel 20 of FIG. 5 is that the capacitor electrode is configured differently. Specifically, a capacitor electrode CSE-C of a pixel structure PX-C of the display panel 20A further overlaps the second extension portion CEs2A of the common electrode CE-A. In this embodiment, the capacitor electrode CSE-C includes only one extension section CSEs1, and the extension section CSEs1 overlaps the second extension portion CEs2A of the common electrode CE-A. Accordingly, by increasing the storage capacitance of the pixel structure PX-C so as to suppress the voltage offset of the pixel electrode PE due to the capacitive coupling effect between the repair pattern RP, the first scan line GL1 (or the second scan line GL2), and the pixel electrode PE, it helps to improve the brightness uniformity of the multiple pixel structures PX-C of the display panel 20A at the same display grayscale.

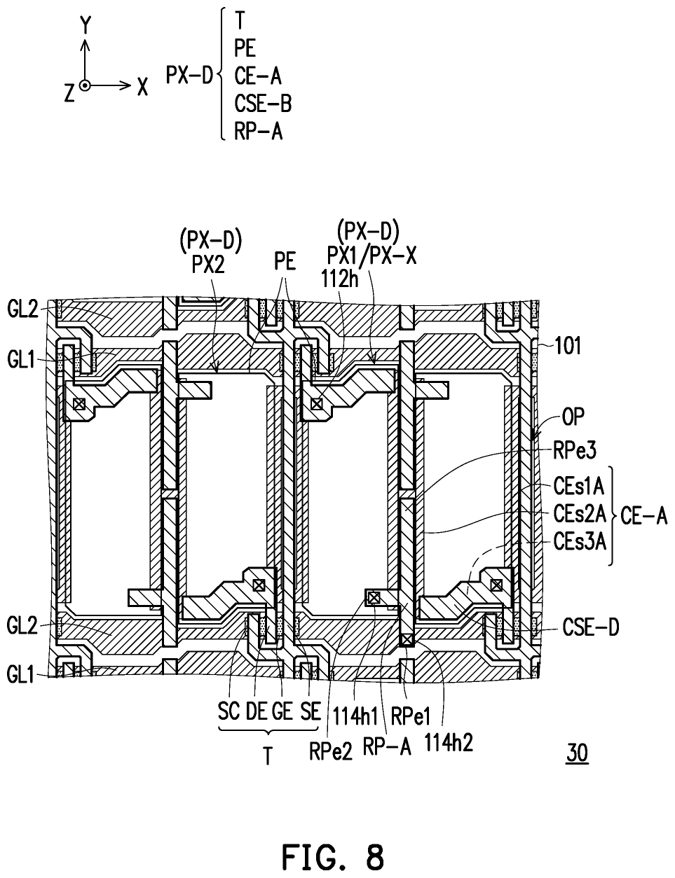

FIG. 8 is a schematic top view of a display panel according to a fifth embodiment of the disclosure. Referring to FIG. 8, the difference between a display panel 30 of this embodiment and the display panel 20 of FIG. 5 is that the repair pattern is configured differently. In this embodiment, the active element T and a repair pattern RP-A of each pixel structure PX-D of the display panel 30 respectively overlap different scan lines, and are electrically independent of each other. For example: the active element T and the repair pattern RP-A of the first pixel structure PX1 respectively overlap the first scan line GL1 and the second scan line GL2, and the active element T and the repair pattern RP-A of the second pixel structure PX2 respectively overlap the second scan line GL2 and the first scan line GL1.

Note in particular that the repair pattern RP-A overlaps the second extension portion CEs2A of the common electrode CE-A, and includes a first end portion RPe 1, a second end portion RPe2, and a third end portion RPe3. The first end portion RPe1 overlaps one scan line. The second end portion RPe2 overlaps the pixel electrode PE. The third end portion RPe3 overlaps the second extension portion CEs2A of the common electrode CE-A. The second end portion RPe2 of the repair pattern RP-A is located between the first end portion RPel and the third end portion RPe3 in the direction Y.

When one of the pixel structures PX-D of the display panel 30, such as the first pixel structure PX1, cannot be enabled and is detected as an abnormal pixel structure PX-X, one laser welding step may be performed to weld the repair pattern RP-A and the corresponding second scan line GL2 to each other to be electrically connected. Since the repair pattern RP-A of the pixel structure PX-D of this embodiment is electrically independent of a capacitor electrode CSE-D and the active element T, another laser welding step is required to weld the second end portion RPe2 of the repair pattern RP-A and the overlapping pixel electrode PE to each other to be electrically connected. Therefore, after the two laser welding steps are completed, the insulating layer or the flat layer between the repair pattern RP-A and the second scan line GL2 will respectively form two melt-through holes 114h1 and 114h2.

The pixel electrode PE of the repaired pixel structure PX-X may further be electrically connected to the second scan line GL2 through the repair pattern RP-A. Therefore, regardless of whether the first scan line GL1 electrically connected to the pixel structure PX-X receives a gate driving signal, the pixel electrode PE of the abnormal pixel structure PX-X always has a higher voltage level. In other words, when the display panel 30 is operated in a normally white mode, the pixel region of the display screen corresponding to the abnormal pixel structure PX-X always maintains a dark state to avoid the degradation of display quality. On the other hand, through the overlap between the capacitor electrode CSE and the common electrode CE, the voltage offset of the pixel electrode PE due to the capacitive coupling effect between the repair pattern RP-A, the scan line, and the pixel electrode PE can be further suppressed, thereby improving the brightness uniformity of the multiple pixel structures PX-D of the display panel 30 at the same display grayscale.

In summary, in the display panel of an embodiment of the disclosure, the pixel structure includes a repair pattern overlapping the scan line, the common electrode, and the pixel electrode, and includes a capacitor electrode extending from the drain of the active element. Through the overlap of the capacitor electrode and the common electrode, the voltage offset of the pixel electrode due to the capacitive coupling effect between the repair pattern, the scan line, and the pixel electrode can be effectively suppressed, thereby improving the brightness uniformity of the multiple pixel structures of the display panel at the same display grayscale.

Finally, it should be noted that the above embodiments are only configured to illustrate the technical solution of the disclosure, but not limited thereto. Although the disclosure is described in detail with reference to the above-mentioned embodiments, those skilled in the art should understand that the technical solutions described in the above-mentioned embodiments may still be modified, and some or all of the technical features may be replaced equivalently; such modifications or replacements do not depart from the scope of the technical solutions described by the embodiments of the disclosure.

What is claimed is:

1. A display panel, comprising:
a first substrate;
a plurality of scan lines, disposed on the first substrate;
a plurality of data lines, disposed on the first substrate and intersecting with the plurality of scan lines; and
a plurality of pixel structures, respectively disposed between the plurality of data lines and the plurality of scan lines, and at least one of the plurality of pixel structures comprises:
an active element, comprising a source, a drain, and a gate, wherein the gate is electrically connected to one of the plurality of scan lines, and the source is electrically connected to one of the plurality of data lines;
a pixel electrode, electrically connected to the drain of the active element;
a capacitor electrode, electrically connected to the pixel electrode and extending from the drain;
a common electrode, overlapping the pixel electrode and the capacitor electrode; and
a repair pattern, overlapping one of the plurality of scan lines as well as the common electrode and the pixel electrode.

2. The display panel of claim 1, wherein the at least one of the plurality of pixel structures comprises a first pixel structure; and
the plurality of scan lines comprise a first scan line, the repair pattern of the pixel structure and a part of the drain overlapping the first scan line.

3. The display panel of claim 2, wherein the repair pattern, the capacitor electrode, and the drain of the active element are integral.

4. The display panel of claim 2, wherein the repair pattern of the first pixel structure and the gate of the active element are electrically connected to the first scan line.

5. The display panel of claim 2, wherein the common electrode comprises a first extension portion, a second extension portion, and a connecting portion;
the first extension portion and the second extension portion are disposed on opposite sides of the pixel electrode along a first direction and extend in a second direction; the connecting portion extends in the first direction;
the connecting portion connects the first extension portion and the second extension portion;
the first direction intersects the second direction; and
the capacitor electrode overlaps the connecting portion of the common electrode.

6. The display panel of claim 5, wherein the capacitor electrode further overlaps one of the first extension portion and the second extension portion of the common electrode.

7. The display panel of claim 5, wherein the plurality of data lines, a plurality of the first extension portions, and a plurality of the second extension portions are alternately arranged along the first direction.

8. The display panel of claim 2, wherein the at least one of the plurality of pixel structures further comprises a second pixel structure;
the first pixel structure and the second pixel structure are arranged along a first direction and are electronically connected to a first data line of the plurality of data lines; the plurality of scan lines further comprise a second scan line;
the first scan line and the second scan line are located on opposite sides of the first pixel structure and the second pixel structure along a second direction;
the first direction intersects the second direction; and
the first pixel structure is electrically connected to the first scan line, the second pixel structure electrically connected to the second scan line.

9. The display panel of claim 8, wherein the common electrode comprises a connecting portion, a first extension portion, and a second extension portion;
the first extension portion and the second extension portion are disposed on opposite sides of the connecting portion along the first direction and are connected to the connecting portion; and
the capacitor electrode overlaps the connecting portion of the common electrode.

10. The display panel of claim 9, wherein the first extension portion of the common electrode of the first pixel structure is connected to the first extension portion of the common electrode of the second pixel structure and defines an opening, and the opening overlaps the first data line.

11. The display panel of claim 9, wherein the capacitor electrode further overlaps the second extension portion of the common electrode.

12. The display panel of claim 1, wherein the at least one of the plurality of pixel structures comprises a first pixel structure; and
the repair pattern of the first pixel structure and the drain of the active element respectively overlap two of the plurality of scan lines.

13. The display panel of claim 12, wherein the at least one of the plurality of pixel structures further comprises a second pixel structure;
the first pixel structure and the second pixel structure are arranged along a first direction and are electrically connected to one of the plurality of data lines;
the plurality of scan lines comprise a first scan line and a second scan line;
the first scan line and the second scan line are located on opposite sides of the first pixel structure and the second pixel structure along a second direction;
the first direction intersects the second direction; and the first pixel structure is electrically connected to the first scan line, the second pixel structure electrically connected to the second scan line.

14. The display panel of claim 13, wherein the common electrode comprises a connecting portion, a first extension portion, and a second extension portion;
the first extension portion and the second extension portion are disposed on opposite sides of the connecting portion along the first direction and are connected to the connecting portion; and
the repair pattern overlaps the second extension portion of the common electrode.

15. The display panel of claim 14, wherein the first extension portion of the common electrode of the first pixel structure is connected to the first extension portion of the common electrode of the second pixel structure and defines an opening, and the opening overlaps one of the plurality of data lines.

16. The display panel of claim 14, wherein the capacitor electrode overlaps the connecting portion of the common electrode.

17. The display panel of claim 14, wherein the repair pattern comprises:
a first end portion, overlapping one of the plurality of scan lines;
a second end portion, overlapping the pixel electrode; and
a third end portion, overlapping the second extension portion of the common electrode, wherein the second end portion is located between the first end portion and the third end portion in the second direction.

18. The display panel of claim 13, wherein the gate of the active element and the repair pattern of the first pixel structure are respectively electrically connected to the first scan line and the second scan line.

19. The display panel of claim 1, further comprising:
a second substrate, disposed opposite to the first substrate;
a first alignment layer, disposed on the first substrate and having a first alignment direction;
a second alignment layer, disposed on the second substrate and having a second alignment direction, wherein the first alignment direction is perpendicular to the second alignment direction;
a liquid crystal layer, disposed between the first alignment layer and the second alignment layer and comprising a plurality of liquid crystal molecules, wherein a plurality of the pixel electrodes of the plurality of pixel structures are configured to drive the plurality of liquid crystal molecules to rotate; and
a first polarizer and a second polarizer, disposed on opposite sides of the liquid crystal layer and respectively comprising a first transmission axis and a second transmission axis, and an axial direction of the first transmission axis is perpendicular to an axial direction of the second transmission axis.

20. The display panel of claim 1, wherein the at least one of the plurality of pixel structures comprises a first pixel structure; and
the pixel electrode of the first pixel structure is electrically connected to one of the scan lines through the repair pattern.
